(19) United States
(12) Patent Application Publication
(10) Pub. No.: US 2024/0028789 A1
(43) Pub. Date: Jan. 25, 2024

(54) DATA CALCULATION DEVICE, DATA CALCULATION METHOD, AND RECORDING MEDIUM

(71) Applicant: NEC Corporation, Minato-ku, Tokyo (JP)

(72) Inventors: Keiichi Kisamori, Tokyo (JP); Yu Kiyokawa, Tokyo (JP)

(73) Assignee: NEC Corporation, Minato-ku, Tokyo (JP)

(21) Appl. No.: 18/025,609

(22) PCT Filed: Sep. 18, 2020
(86) PCT No.: PCT/JP2020/035546

§ 371 Date: Mar. 9, 2023

(51) Int. Cl. G06F 30/20

(52) U.S. Cl. CPC G06F 30/20

(57) ABSTRACT

A data calculation device including a high-level posterior distribution data calculator for calculating data indicating a posterior distribution of parameter values of a high-level model that simulates a subject, based on target data for outputs from the high-level model; and a low-level posterior distribution data calculator for calculating, for a low-level model that simulates a portion of the subject and that outputs parameter values of the high-level model, data indicating a posterior distribution of parameter values of the low-level model, based on the data indicating a posterior distribution of parameter values of the high-level model.

### TECHNICAL FIELD

The present invention relates to a data calculation device, a data calculation method, and a recording medium.

### BACKGROUND ART

Technology has been proposed for estimating, based on target data corresponding to outputs from a simulator, parameter values such that the simulator outputs that target data. For example, Patent Document 1 describes using kernel ABC (Kernel Approximate Bayesian Computation) and kernel herding to calculate a posterior distribution of parameter values in accordance with target data.

### CITATION LIST

### Patent Literature

[Patent Document 1] WO 2020/105468 A1

### SUMMARY OF INVENTION

### Problems to be Solved by the Invention

In cases in which there are a large number of parameters for which values are to be estimated, such as in cases in which the scale of a simulation subject is large, a long time can be expected to be required for estimating the parameter values. In particular, the time required to estimate parameter values can be expected to increase exponentially in response to increases in the number of parameters for which the values are to be estimated. For this reason, in the case in which there is a large number of parameters for which the values are to be estimated, the estimated values of the parameters may not be able to be obtained within a practical time period.

One example object of the present invention is to provide a data calculation device, a data calculation method, and a recording medium that can solve the above-mentioned problem.

### Means for Solving the Problems

According to a first embodiment of the present invention, a data calculation device comprises high-level posterior distribution data calculating means for calculating data indicating a posterior distribution of parameter values of a high-level model that simulates a subject, based on target data for outputs from the high-level model; and low-level posterior distribution data calculating means for calculating, for a low-level model that simulates a portion of the subject and that outputs parameter values of the high-level model, data indicating a posterior distribution of parameter values of the low-level model, based on the data indicating a posterior distribution of parameter values of the high-level model.

According to a second embodiment of the present invention, a data calculation device comprises low-level model simulation executing means for executing a simulation by applying, to a low-level model that outputs parameter values of a high-level model that simulates a subject, data indicating a distribution of parameter values of the low-level model, thereby calculating data indicating a distribution of the parameter values of the high-level model; and high-level model simulation executing means for executing a simulation of the subject by applying, to the high-level model, the data indicating a distribution of parameter values that have been calculated.

According to a third embodiment of the present invention, a data calculation method involves a computer calculating data indicating a posterior distribution of parameter values of a high-level model that simulates a subject, based on target data for outputs from the high-level model; and calculating, for a low-level model that simulates a portion of the subject and that outputs parameter values of the high-level model, data indicating a posterior distribution of parameter values of the low-level model, based on the data indicating a posterior distribution of parameter values of the high-level model.

According to a fourth embodiment of the present invention, a recording medium has, recorded thereon, a program for making a computer execute steps of calculating data indicating a posterior distribution of parameter values of a high-level model that simulates a subject, based on target data for outputs from the high-level model; and calculating, for a low-level model that simulates a portion of the subject and that outputs parameter values of the high-level model, data indicating a posterior distribution of parameter values of the low-level model, based on the data indicating a posterior distribution of parameter values of the high-level model.

### Advantageous Effects of Invention

According to the data calculation device, the data calculation method, and the recording medium of the present invention, even in cases in which there are a large number of parameters for which the values are to be estimated based on the output from a simulator, the values can be estimated in a relatively short time period.

### BRIEF DESCRIPTION OF DRAWINGS

FIG. 1 is a schematic block diagram depicting the functional configuration of a data calculation device according to an example embodiment.

FIG. 2 is a diagram depicting an example of a model of a subject used by the data calculation device according to the example embodiment.

FIG. 3 is a flow chart depicting an example of a processing procedure by which the data calculation device according to the example embodiment performs hierarchical data assimilation.

FIG. 4 is a flow chart depicting an example of a processing procedure performed for each low-level model by the data calculation device according to the example embodiment.

FIG. 5 is a diagram depicting the configuration of a production system constituting an example of a subject according to the example embodiment.

FIG. 6 is a diagram depicting an example of a model simulating a production system according to the example embodiment.

FIG. 7 is a diagram depicting an example of samples of parameter values in a high-level model based on a prior distribution according to the example embodiment.

FIG. 8 is a diagram depicting a first example of samples of output values in the high-level model according to the example embodiment.

FIG. 9 is a diagram depicting an example of samples of parameter values in the high-level model based on a posterior distribution according to the example embodiment.

FIG. 10 is a diagram depicting an example of samples of parameter values in low-level models based on prior distributions according to the example embodiment.

FIG. 11 is a diagram depicting an example of samples of output values in the low-level models according to the example embodiment.

FIG. 12 is a diagram depicting an example of samples of parameter values in the low-level model based on posterior distributions according to the example embodiment.

FIG. 13 is a diagram depicting an example of samples of output values in a low-level model according to the example embodiment.

FIG. 14 is a diagram depicting a second example of samples of output values in the low-level model according to the example embodiment.

FIG. 15 is a diagram depicting a third example of samples of parameter values in a high-level model according to the example embodiment.

FIG. 16 is a diagram depicting an example of estimation results for parameter values in low-level models by a data calculation device according to the example embodiment.

FIG. 17 is a diagram depicting an example of the input/output of data in an intermediate layer in the case in which there are three or more layers in a model according to an example embodiment.

FIG. 18 is a diagram depicting an example of the configuration of a data calculation device according to an example embodiment.

FIG. 19 is a diagram depicting one more example of the configuration of a data calculation device according to an example embodiment.

FIG. 20 is a diagram depicting an example of the processing procedure in a data calculation method according to an example embodiment.

FIG. 21 is a schematic block diagram depicting the configuration of a computer according to at least one example embodiment.

### EXAMPLE EMBODIMENT

Hereinafter, example embodiments of the present invention will be explained. However, the example embodiments below should not be construed as limiting the invention as claimed. Additionally, not all combinations of the characteristics described among the example embodiments are necessarily essential for the solution provided by the invention.

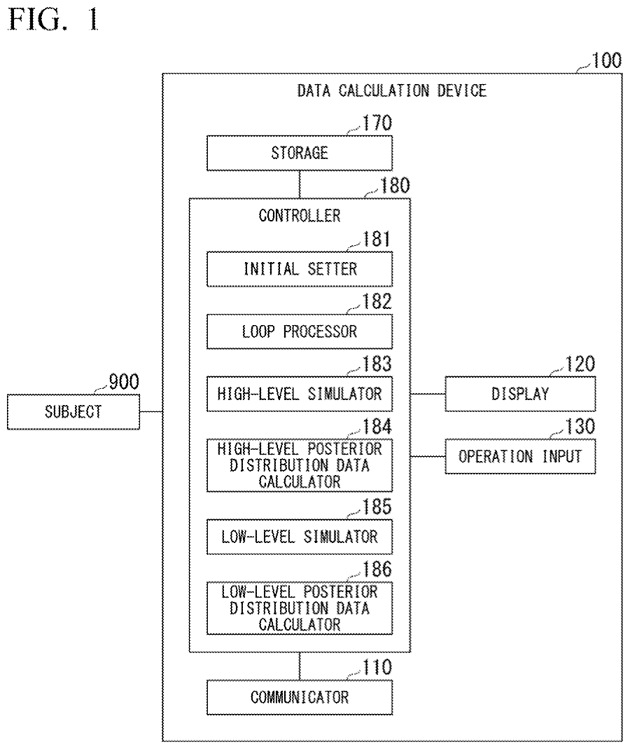

FIG. 1 is a schematic block diagram depicting the functional configuration of a data calculation device according to an example embodiment. In the configuration depicted in FIG. 1, the data calculation device 100 comprises a communicator 110, a display 120, an operation input 130, a storage 170, and a controller 180. The controller 180 comprises an initial setter 181, a loop processor 182, a high-level simulator 183, a high-level posterior distribution data calculator 184, a low-level simulator 185, and a low-level posterior distribution data calculator 186.

Additionally, FIG. 1 depicts a subject 900 that is the subject of a simulation by a simulation model. The simulation model of the subject 900 will also be referred to as a model of the subject 900, or simply as a model.

The data calculation device 100 uses target data for outputs from the model and estimates parameter values of the model so that the output values from the model approach the values of the target data. The data calculation device 100 may be configured by using a computer such as, for example, a workstation or a personal computer (PC).

The data calculation device 100 may be configured as a single device or may be configured by combining multiple devices. For example, the high-level simulator 183 and the low-level simulator 185 may be configured as separate simulator devices for each model.

The values of the target data are also referred to as target values. The process of estimating the parameter values of a model so that the output values from the model approach the target values is also referred to as data assimilation. The estimation of parameter values in data assimilation is also referred to as adjustment of the parameter values.

The target data may be measurement data in the subject 900. In this case, the model can be adjusted to be able to simulate the subject 900 with high accuracy by the data calculation device 100 estimating the parameter values.

Additionally, the state of the subject 900 can be estimated by referencing the parameter values that are the estimation results. For example, if the subject 900 is a factory and the parameters to be estimated by the data calculation device 100 are production amounts for the respective production lines in the factory, then the parameter values estimated by the data calculation device 100 can be used as the production amounts for the respective production lines in the factory estimated from the measurement data.

Alternatively, the target data may be data indicating target values in the subject 900. In this case, strategies may be prepared for achieving the targets by referencing the parameters that are the estimation results by the data calculation device 100. Furthermore, according to the data calculation device 100, the subject 900 can be controlled, such as by controlling the respective apparatuses in the factory based on the prepared strategies.

For example, if the subject 900 is a factory and the parameters to be estimated by the data calculation device 100 are production amounts for the respective production lines in the factory, then the parameter values estimated by the data calculation device 100 can be used as the production amounts for the respective production lines in the factory for achieving the target values indicated by the target data.

According to the data calculation device 100, control based on the estimation results can be implemented, such as by controlling the equipment in the respective production lines based on the production amounts estimated for the respective production lines in the factory.

The data calculation device 100 uses a hierarchical model as the model for simulating the subject 900. For example, the data calculation device 100 may use a model including a high-level model simulating the subject 900 as a whole and one or more low-level models simulating a part of the subject 900.

The “hierarchy” mentioned here means that high-low relationships can be defined. For example, as mentioned above, based on the relationship between the whole and the parts, a model simulating the subject 900 as a whole may be a high-level model and a model simulating a part of the subject 900 may be a low-level model. This high-low relationship may be fixed or may be variable. For example, in a model simulating a company, a model of the accounting department would be a high-level model for the flow of expenses, but a model of the purchasing department would be a high-level model for the flow of materials. Thus, the high-low relationship may differ in accordance with the purpose of the data calculation.

Furthermore, the data calculation device 100 uses a hierarchical model in which a low-level model outputs the parameter values for a high-level model. Thus, the data calculation device 100 repeats the process of estimating the parameter values of a model based on target data output by the model in accordance with the hierarchical structure of the model.

For example, the data calculation device 100 estimates parameter values of a high-level model based on target data for outputs from the high-level model. Furthermore, the data calculation device 100 uses the estimated parameter values of the high-level model as target data for the outputs from the low-level model to estimate the parameter values of the low-level model.

In this way, by having the data calculation device 100 hierarchically estimate the parameter values of models in accordance with the hierarchical structure of the models, the number of parameters in each model can be reduced in comparison with the case in which the subject 900 is simulated by only one model. For example, for the parameters in the high-level model, by using the production amounts for the respective sections that include multiple production lines as the parameters, the number of parameters in the high-level model can be reduced with respect to the case in which the production amounts of each of the production lines are used as the parameters.

In this case, if there are many parameters in a model, then the estimation of parameter values can be expected to take a long time. In particular, the time required for estimating the parameter values can be expected to increase exponentially as the number of parameters increases. For this reason, if there are many parameters, then the estimated values of the parameters might not to be obtainable within a realistic time period.

In contrast therewith, with the data calculation device 100, by using a hierarchical model in which the number of parameters in each model is relatively small, as described above, the computation time can be expected to be shorter than that in the case in which a single model with a large number of parameters is used.

The subject 900 is a subject simulated by the data calculation device 100. The subject 900 may be various systems that can be simulated by using a hierarchical simulation model.

For example, the subject 900 may be a factory. Furthermore, the data calculation device 100 may use a hierarchical model including a high-level model simulating the whole factory, and one or more low-level models simulating parts of the factory.

Alternatively, the subject 900 may be a supply chain including production sites, distribution facilities, and sales sites. Furthermore, the data calculation device 100 may use a hierarchical model including a high-level model that simulates the whole supply chain, and low-level models that simulate, respectively, the production sites, the distribution facilities, and the sales sites.

Alternatively, the subject 900 may be a certain geographical region. Furthermore, the data calculation device 100 may use a hierarchical model including a high-level model that simulates infection spreading conditions in the entire region, and low-level models that simulate the infection conditions in parts of that geographical region or in transportation systems therein.

The subject 900 may really exist or may be virtual.

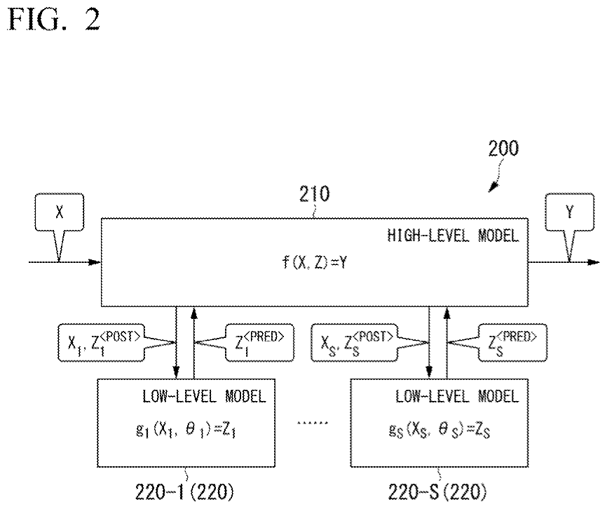

FIG. 2 is a diagram depicting an example of a model of the subject 900 used by the data calculation device 100. In the example in FIG. 2, the model 200 includes one high-level model 210 and S low-level models 220-1 to 220-S. S is an integer such that S≥1, representing the number of low-level models 220. The low-level models 220-1 to 220-S will also be referred to collectively as low-level models 220.

The inputs to the high-level model 210 are indicated by the vector X, the parameters of the high-level model 210 are indicated by the vector Z, and the outputs from the high-level model 210 are indicated by the vector Y. The vectors X, Y, and Z are all real vectors. The number of dimensions of the vectors X and Y may be one or more dimensions. The number of dimensions of the vector Z may be S or more dimensions.

The vector X will also be referred to as the input vector X. The vector Y will also be referred to as the output vector Y. The vector Z will also be referred to as the parameter vector Z.

The elements of the input vector X may include elements having discrete values such as integer values or binary values. Similarly, the elements of the output vector Y may include elements having discrete values such as integer values or binary values.

The elements of the parameter vector Z may include elements having discrete values such as integer values or binary values. The high-level model 210 is represented by f, and is denoted f(X, Z)=Y. Alternatively, the input vector X may be omitted so as to be denoted f(Z)=Y.

The inputs to the low-level models 220-s are represented by the vectors Xₛ, the parameters of the low-level models 220-s are represented by the vectors θₛ, and the outputs from the low-level models 220-s are represented by the vectors Zₛ. The symbol s represents an integer such that 1≤s≤S.

The vectors Xₛ, Zₛ, and θₛ are all real vectors. The number of dimensions in each of Xₛ, and the vectors Zₛ and θₛ may be one or more dimensions. The number of dimensions in Xₛ may be zero or more dimensions.

The elements of the input vectors Xₛ may include elements having discrete values, such as integer values or binary values. Similarly, the elements of the output vectors Zₛ may include elements having discrete values, such as integer values or binary values. The elements of the parameter vectors θₛ may include elements having discrete values, such as integer values or binary values.

The low-level models 220 are represented by gₛ, and are denoted gₛ(Xₛ, θₛ)=Zₛ. Alternatively, the input vectors Xₛ may be omitted so as to be denoted gₛ(θₛ)=Zₛ.

The data calculation device 100 acquires target data representing combinations of values of the input vector X and values of the output vector Y, and adjusts the values of the parameter vector Z so that the output values from the high-level model 210 approach target values.

The probability distribution of the parameter vector Z before adjustment by the data calculation device 100 is denoted by the prior distribution π_{Z}, and the values of the parameter vector Z due to the prior distribution π_{Z} are denoted by the samples Z^{<PRI>}. The probability distribution of a vector may be indicated by a combination of the probability distributions for each element of the vector.

The prior distribution π_{Z} may be set by the user based on information regarding the subject 900. Alternatively, a prescribed distribution, such as a uniform distribution, may be used as the prior distribution π_{Z}.

The probability distribution of the parameter vector Z after adjustment by the data calculation device 100 is denoted by the posterior distribution p(Z|Y), and the values of the parameter vector Z according to the posterior distribution p(Z|Y) are denoted by the samples Z^{<POST>}. The posterior distribution p(Z|Y) in this case refers to the posterior distribution of the values of the parameter vector Z when provided with the target values of the output vector Y.

Additionally, the data calculation device 100 decides the input values (the values of the input vectors Xₛ) to the low-level models 220-s based on the input values (the values of the input vector X) to the high-level model 210. For example, the vector spaces of the input vectors Xₛ may be partial spaces of the vector space of the input vector X. That is, the input vectors Xₛ may be configured by using some of the elements of the input vector X. In this case, the data calculation device 100 sets the values of elements of the input vector X as the values of elements of the input vectors Xₛ in accordance with the relationship between the input vector X and the input vectors Xₛ.

Alternatively, the values of the elements of the input vectors Xₛ may include values computed on the basis of the values of the input vector X.

Additionally, the data calculation device 100 decides target values for the outputs of the low-level models 220-s based on the samples Z^{<POST>}. For example, the vector spaces of the output vectors Zₛ may be partial spaces of the vector space of the parameter vector Z. That is, the output vectors Zₛ may be configured by using some of the elements of the parameter vector Z. In this case, the data calculation device 100 sets the values of the elements of the samples Z^{<POST>} to be the values of the elements of the output vectors Zₛ in the target data for the outputs from the low-level models 220-s in accordance with the relationship between the parameter vector Z and the output vectors Zₛ.

Among the elements of the parameter vector Z, there may be elements that are not linked to the output vectors Zₛ. That is, the parameters of the high-level model 210 may be parameters that are used for computing the high-level model 210, but that are not values output by the low-level models 220.

The target values of the outputs from the low-level models 220-s decided by the data calculation device 100 on the basis of the samples Z^{<POST>} are denoted by the samples Z^{<POST>}ₛ.

In this way, the data calculation device 100 can hierarchically perform data assimilation by setting parameter values of the high-level model 210 to be target data for the output values from the low-level models 220. Specifically, the data calculation device 100 can allow the adjustment results in the high-level model 210 to be reflected in the adjustment of the parameter values in the low-level models 220 by deciding target values (samples Z^{<POST>}ₛ) of the outputs from the low-level models 220 on the basis of the samples Z^{<POST>} after adjustment of the parameter values in the high-level model 210.

The number of dimensions in the parameter vector Z is less than the sum of the number of dimensions in the parameter vectors θ₁ to θ_{S}. Thus, the number of parameters in each model can be reduced relative to the case in which the subject 900 is simulated with only one model. For this reason, according to the data calculation device 100, it is expected that data assimilation can be performed and the values of the parameter vectors θ₁ to θ_{S} can be estimated in a relatively short time period. In particular, according to the data calculation device 100, it is expected to be possible to avoid estimated values of the parameters not being able to be obtained within a practical time period due to there being a large number of parameters in a model.

Additionally, the data calculation device 100, for each low-level model 220, performs data assimilation for adjusting the values of the parameter vectors θₛ so that the values of the output vector Z, approach the samples Z^{<POST>}ₛ.

The probability distributions of the parameter vectors θₛ before the adjustment by the data calculation device 100 are denoted by the prior distributions ζ_{θs}, and the values of the parameter vectors θₛ based on the prior distributions no s are denoted by the samples θ^{<PRI>}ₛ.

The prior distributions no, may be set by the user based on information regarding the subject 900. Alternatively, prescribed distributions such as a uniform distribution may be used as the prior distributions nos.

The probability distribution of the parameter vector Z after adjustment by the data calculation device 100 is denoted by the posterior distribution p(θₛ|Zₛ), and the values of the parameter vector Z based on the posterior distribution p(θₛ|Zₛ) are denoted by the samples θ^{<POST>}ₛ.

Additionally, the data calculation device 100 executes simulations by applying the samples θ^{<POST>}ₛ as the parameters of the low-level models 220-s, thereby calculating the output vectors Zₛ corresponding to the input vectors Xₛ. Applying samples of the parameters as the parameters of the model means setting the sample values as the parameter values. Applying samples as the parameters of a model is also referred to as applying samples to a model. The values of the output vectors Zₛ calculated by simulations to which the samples θ^{<POST>}ₛ have been applied are denoted by the samples Z^{<PRED>}ₛ.

Furthermore, the data calculation device 100 generates samples of the values of the parameter vector Z based on the values from sample Z^{<PRED>}₁ to sample Z^{<PRED>}_{S}. These samples are used by the data calculation device 100 as samples reflecting the results of data assimilation in the low-level models 220 when repeatedly performing data assimilation using the high-level model 210.

If the elements in the parameter vector Z are each linked to at most one of the elements from the sample Z^{<PRED>}₁ to the sample Z^{<PRED>}_{S}, then in accordance with this relationship, the data calculation device 100 may use the values of the elements from the sample Z^{<PRED>}₁ to the sample Z^{<PRED>}_{S} as the values of the elements of the samples being generated.

Alternatively, the elements of the parameter vector Z may include elements that are linked with multiple elements from the sample Z^{<PRED>}₁ to the sample Z^{<PRED>}_{S}. In this case, the data calculation device 100 may calculate the values of the elements of the samples being generated by a prescribed method, such as taking the mean of the values of the multiple elements from the sample Z^{<PRED>}₁ to the sample Z^{<PRED>}_{S}.

Thus, the data calculation device 100 can repeatedly perform hierarchical data assimilation by generating samples of the parameter vector Z based on the values from the sample Z^{<PRED>}₁ to the sample Z^{<PRED>}_{S}.

Specifically, the data calculation device 100 executes simulations by applying the values of the generated samples to the parameter vector Z of the high-level model 210. In this way, the data calculation device 100 acquires samples of the output vector Y based on samples of the generated parameters. Then, the data calculation device 100 estimates the values of the parameter vector Z, based on the relationships between the target values and the samples of the output vector Y that have been obtained, so that the output values from the high-level model 210 approach the target values. The data calculation device 100 uses the estimated values of the parameter vector Z as the samples Z^{<POST>}, and as mentioned above, performs data assimilation in the low-level models 220 to generate samples of the parameter vector Z based on the results of the data assimilation. The data calculation device 100 repeatedly performs hierarchical data assimilation until prescribed ending conditions are established.

Due to the data calculation device 100 repeatedly performing hierarchical data assimilation in this way, it is expected that parameter values can be estimated with high accuracy. In particular, the probability distribution of the parameter vector Z and the respective probability distributions of the parameter vectors θ₁ to θₛ are all expected to converge to certain parameter values in accordance with the target values. The probability distributions converging to certain parameter values as mentioned here means that the probabilities become larger at those values.

For example, due to data assimilation, the probabilities of the values of the parameters Z resulting in the values of the output vector Y approaching the target values become relatively larger, and as a result thereof, when data assimilation is performed again, more of the sampled values of the output vector Y are close to the target values. In this way, performing data assimilation again can be expected to further increase the probabilities that the values of the parameters Z will result in the values of the output vector Y becoming values close to the target values.

By repeatedly performing data assimilation for the parameter vectors θ₁ to θ_{S} also, the probabilities of the parameter values being in accordance with the target values can be expected to become larger.

Hereinafter, an example of the case in which the data calculation device 100 uses kernel ABC and kernel herding as the processes for estimating the parameter values for making the output values of the model approach the target values will be explained.

However, the method by which the data calculation device 100 estimates parameter values so that the output values of the model approach the target values is not limited to a specific method. For example, the data calculation device 100 may use the Markov Chain Monte Carlo (MCMC) method or the ABC (Approximate Bayesian Computation) method as the process for estimating the parameters values so that the output values from the model approach the target values.

The communicator 110 communicates with other devices. For example, in the case in which the data calculation device 100 acquires measurement data from a sensor as the target data, the communicator 110 may receive, from the sensor installed in the subject 900, the measurement data from that sensor.

The display 120 is provided with a display screen such as, for example, a liquid-crystal display panel or an LED (Light-Emitting Diode) panel, and displays various types of images. For example, the display 120 may display parameter value estimation results from the data calculation device 100.

The operation input 130 is provided with an input device such as, for example, a keyboard and a mouse, and receives user operations. For example, the operation input 130 may receive user operations for inputting target values in the subject 900 as the target data.

The storage 170 stores various types of data. For example, the storage 170 stores a hierarchized model, as mentioned above, as a model for the subject 900. The storage 170 is configured by using a storage device provided in the data calculation device 100.

The controller 180 controls the units in the data calculation device 100 to perform various types of processes. The functions of the controller 180 may be executed by a CPU (Central Processing Unit) provided in the data calculation device 100 reading out and executing a program from the storage 170.

The initial setter 181 performs initial settings for hierarchical data assimilation.

Specifically, the initial setter 181 substitutes the numeral 1 into a variable l used as a loop counter for repeating hierarchical data assimilation.

Additionally, the initial setter 181 performs sampling based on the prior distribution π_{Z} of the parameter vector Z. That is, samples Z^{<PRI>} are calculated based on the prior distribution π_{Z}. The initial setter 181 calculates M samples M is an integer such that M≥1, indicating the number of samples. The M samples Z^{<PRI>(l)} obtained by the sampling of the initial setter 181 are denoted by {Z^{<PRI>(l)}ₘ}ₘ₌₁^{M}. The value inside the parentheses is the value of the variable 1. That is, the value in the parentheses indicates how many times the hierarchical data assimilation has been executed. The “m” that is the subscript in “Z^{<PRI>(l)}ₘ” represents an identification number for identifying the M samples Z^{<PRI>(l)}.

The loop processor 182 performs a loop process in which hierarchical data assimilation is repeated. Specifically, the loop processor 182 counts up values of the variable l in accordance with the number of times the hierarchical data assimilation has been repeated. Additionally, the loop processor 182 determines whether or not loop ending conditions have been established.

Various conditions can be used as the loop ending conditions mentioned here. For example, the loop ending conditions may be that the value of the variable l is a prescribed threshold value or higher. Alternatively, the loop ending conditions may be that the output values of the high-level model 210 have been assessed to be as close as or closer to the target values than prescribed conditions.

The high-level simulator 183 executes simulations using the high-level model 210.

In particular, the high-level simulator 183 executes simulations by applying, to the high-level model 210, the values of the parameter vector Z after being updated based on the samples Z^{<PRED>}₁ to Z^{<PRED>}_{S} obtained as a result of the simulations using the low-level models 220.

The high-level simulator 183 corresponds to an example of high-level simulator 183 high-level model simulation executing means.

The values of the parameter vector Z after being updated based on the samples Z^{<PRED>}₁ to Z^{<PRED>}_{S} are denoted by the samples Z^{<PRI>(l+1)}. As mentioned above, the value in the parentheses is the value of the variable 1.

The high-level simulator 183 acquires the samples Z^{<PRI>(l+1)} for the (l+1)-th hierarchical data assimilation based on the samples Z^{<PRED>(l)}₁ to Z^{<PRED>(l)}_{S} obtained by the l-th execution of the hierarchical data assimilation. In the data calculation device 100, as mentioned above, the high-level simulator 183 may use the values of the elements of the samples Z^{<PRED>(l)}ₛ as the values of the elements of the samples Z^{<PRI>(l+1)}. Alternatively, in the data calculation device 100, as mentioned above, the high-level simulator 183 may calculate values of the elements of the samples Z^{<PRED>(l)}ₛ by a prescribed method, such as by taking the mean of the values of the multiple elements from the sample Z<PRED>₁ to the sample Z^{<PRED>}_{S}.

The high-level simulator 183 executes simulations by applying the samples Z^{<PRI>(l+1)} to the high-level model 210, thereby calculating the samples Y^{<PRI>(l+1)}.

The high-level simulator 183 acquires M combinations from the samples Z^{<PRED>(l)}₁ to Z^{<PRED>(l)}_{S}, calculates M samples Z^{<PRI>(l+1)}, and calculates M samples Y^{<PRI>(l+1)}. The M samples Z^{<PRI>(l)} calculated by the high-level simulator 183 are denoted by {Z^{<PRI>(l)}ₘ}ₘ₌₁^{M}. The M samples Y^{<PRI>(l)} calculated by the high-level simulator 183 are denoted by {Y^{<PRI>(l)}ₘ}ₘ₌₁^{M}. The “m” that is the subscript in “Z^{<PRI>(l)}ₘ” and the “m” that is the subscript in “Y^{<PRI>(l)}ₘ” both represent identification numbers for identifying the M samples.

The high-level posterior distribution data calculator 184 calculates data indicating the posterior distribution of the values of the parameter vector Z of the high-level model 210 based on the target data for the output vector Y of the high-level model 210. The high-level posterior distribution data calculator 184 corresponds to an example of high-level posterior distribution data calculating means.

Specifically, the high-level posterior distribution data calculator 184 uses kernel ABC and kernel herding to perform data assimilation for estimating the values of the parameter vector Z such that the values of the output vector Y approach the target values. The high-level posterior distribution data calculator 184, by this data assimilation, calculates M samples Z^{<POST>(l)} in accordance with the M samples {Z^{<PRI(l)>}ₘ}ₘ₌₁^{M}. As mentioned above, the value in the parentheses is the value of the variable 1.

The M samples Z^{<POST>(l)} calculated by the high-level posterior distribution data calculator 184 are denoted by {Z^{<POST>(l)}ₘ}ₘ₌₁^{M}. The “m” that is the subscript in “Z^{<POST>(l)}ₘ” represent identification numbers each identifying M samples “Z^{<POST>(l)}”. The M samples {Z^{<POST>(l)}ₘ}ₘ₌₁^{M} correspond to examples of data representing a posterior distribution p(Z|Y) of values of the parameter vector Z for the high-level model 210 based on the target data.

The high-level posterior distribution data calculator 184, when executing kernel ABC, projects the target values and each of {Y^{<PRI>(l)}ₘ}ₘ₌₁^{M} to points in a reproducing kernel Hilbert space (RKHS). Furthermore, the high-level posterior distribution data calculator 184 calculates a kernel mean based on the distances, in the reproducing kernel Hilbert space, between the points obtained by projecting the target values and the points obtained by projecting the samples Y^{<PRI>(l)}ₘ. The high-level posterior distribution data calculator 184 applies kernel herding to the calculated kernel mean to calculate {Z^{<POST>(l)}ₘ}ₘ₌₁^{M}.

The distances in the reproducing kernel Hilbert space correspond to examples of indices indicating the similarity between the samples Y^{<PRI>(l)}ₘ and the target values. The higher the similarity between the samples Y^{<PRI>(l)}ₘ and the target values is, the smaller the distances are in the reproducing kernel Hilbert space.

The low-level simulator 185 executes simulations using the low-level models 220.

In particular, the low-level simulator 185, as mentioned above regarding the data calculation device 100, calculates the samples Z^{<PRED>}ₛ by executing simulations by applying, to the low-level models 220-s, samples θ^{<POST>}ₛ that have been obtained by data assimilation in the low-level model 220-s. Data assimilation in the low-level models 220-s, as mentioned above, is data assimilation for estimating the values of the parameter vectors θₛ for the low-level models 220 such that the values of the output vectors Zₛ of the low-level models 220-s approach the target values (samples Z^{<POST>}ₛ).

The low-level simulator 185 acquires M samples θ^{<POST>}ₛ calculated by data assimilation by the low-level posterior distribution data calculator 186, and calculates M samples Z^{<PRED>}ₛ. The low-level simulator 185 corresponds to an example of low-level model simulation executing means.

The M samples θ^{<POST>}ₛ calculated by the low-level posterior distribution data calculator 186 are denoted by {θ^{<POST>(l)}ₘ}ₘ₌₁^{M}. As mentioned above, the value in the parentheses is the value of the variable l. The “m” that is the subscript in “θ^{<POST>(l)}ₘ” represents an identification number for identifying the M samples θ^{<POST>(l)}.

The M samples Z^{<PRED>}ₛ calculated by the low-level simulator 185 are denoted by {Z^{<PRED>(l)}_{s,m}}ₘ₌₁^{M}. As mentioned above, the value in the parentheses is the value of the variable 1. The “m” that is the subscript in “Z^{<PRED>(l)}_{s,m}” represents an identification number for identifying the M samples Z^{<PRED>(l)}ₛ.

The low-level posterior distribution data calculator 186 calculates data representing posterior distributions of the parameters values for the low-level models 220 based on data representing the posterior distribution p(Z|Y) of the parameter vector Z for the high-level model 210. The low-level posterior distribution data calculator 186 corresponds to an example of low-level posterior distribution data calculating means.

Specifically, the low-level posterior distribution data calculator 186 uses kernel ABC and kernel herding to perform data assimilation for estimating the values of the parameters θₛ such that the output values of the low-level model 220-s approach the samples Z^{<POST>(l)}, which are the target values.

The low-level posterior distribution data calculator 186, by this data assimilation, calculates the M samples {θ^{<POST>(l)}ₘ}ₘ₌₁^{M} as mentioned above.

The controller 180 may control the subject 900, such as by transmitting control signals to the subject 900 via the communicator 110. For example, the controller 180 may control the respective units in the subject 900, such as respective devices in the subject 900, based on parameter estimation results for the model 200 or based on simulation execution results using the model 200. Furthermore, for example, the controller 180 may control the subject 900 based on data (the samples {θ^{<POST>(l)}ₘ}ₘ₌₁^{M}) representing a posterior distribution of the parameter values of the low-level models 220 calculated by the low-level posterior distribution data calculator 186.

The controller 180 corresponds to an example of controlling means.

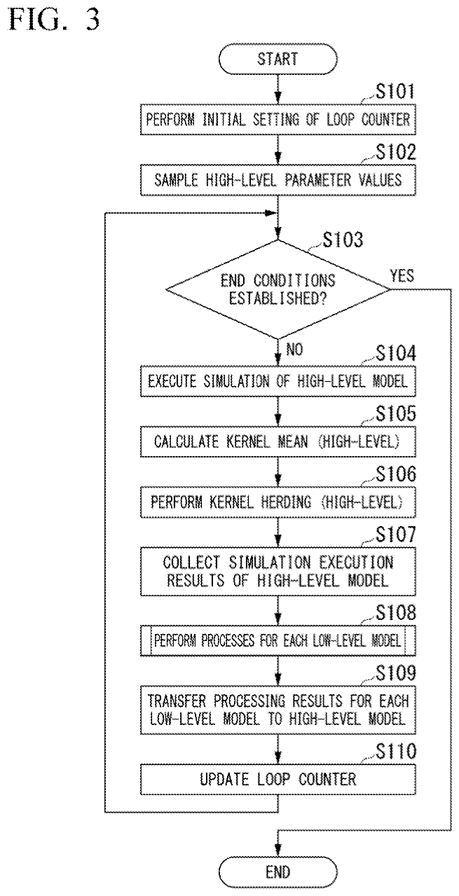

FIG. 3 is a flow chart depicting an example of a processing procedure by which the data calculation device 100 performs hierarchical data assimilation.

### (Step S101)

The initial setter 181 initially sets the value of the variable l used as the loop counter. Specifically, the initial setter 181 sets the value of the variable l to 1. The value of the variable l represents the number of times that the loop from steps S103 to S220 have been repeated.

After step S101, the process shifts to step S102.

### (Step S102)

The initial setter 181 computes M samples {Z^{<PRI>(l)}ₘ}ₘ₌₁^{M} from the prior distribution π_{Z} of the parameter vector Z.

After step S102, the process shifts to step S103.

### (Step S103)

The loop processor 182 determines whether or not loop ending conditions are established.

If the loop processor 182 has determined that the ending conditions have not been established (step S103: NO), then the process shifts to step S104.

Meanwhile, if the loop processor 182 has determined that the ending conditions have been established (step S103: YES), then the data calculation device 100 ends the process in FIG. 3.

### (Step S104)

The high-level simulator 183 executes a simulation by setting the samples Z^{<PRI>(l)}ₘ (m=1, . . . , M) as the parameters of the high-level model 210, thereby calculating the output samples Y^{<PRI>(l)}ₘ. Y^{<PRI>(l)}ₘ can be expressed as in Expression (1).

[Mathematical Expression 1]

[symbol]

=f( [symbol] ) (1)

After step S104, the process shifts to step S105.

### (Step S105)

The high-level posterior distribution data calculator 184 calculates the kernel mean μ\hat{ }^{(l)}_{Z|Y}. The kernel mean μ\hat{ }^{(l)}_{Z|Y} can be expressed as in Expression (2).

$$\begin{matrix}[ Mathematical Expression 2 ] & \\ {{μ}^{\hat{}}}_{Z \vert Y}^{( l )} = {{\sum }_{m = 1}}^{M} {w}_{m} {k}_{Z} ( \cdot , {Z}_{m}^{〈 PRI 〉 ( l )} ) & ( 2 )\end{matrix}$$

k_{Z} represents a kernel.

The “⋅” in the parentheses indicates that the variables of the function in the reproducing kernel Hilbert space are not limited to specific variables.

The weight wₘ can be expressed as in Expression (3).

[Mathematical Expression 3]

(w₁, . . . , w_{M})^{T}=(G_{y}+δMI)⁻¹K_{y}(Y) (3)

The “I” represents a unit matrix.

δ represents a regularization constant, where δ>0.

G_{y} represents a Gram matrix, which can be expressed as in Expression (4).

[Mathematical Expression 4]

G_{y}={k_{y}( [symbol] , [symbol] )}_{m,m′=1}^{M} (4)

k_{y}(Y) represents a kernel of y, and can be expressed as in Expression (5).

[Mathematical Expression 5]

K_{y}(Y)=(k_{y}( [symbol] ,Y), . . . , k_{y}( [symbol] , Y))^{T} (5)

The superscript T represents a transpose of a matrix or a vector.

After step S105, the process shifts to step S106.

### (Step S106)

The high-level posterior distribution data calculator 184 calculates samples {Z^{<POST>(l)}ₘ}ₘ₌₁^{M} of the parameter Z by the kernel mean μ\hat{ }^{(l)}_{Z|Y}.

The kernel mean μ\hat{ }^{(l)}_{Z|Y} is linked, in a one-to-one correspondence, to the posterior distribution p(Z|Y) for the case in which the target data is provided as the output vector Y. By performing a kernel herding process, samples based on the posterior distribution are obtained.

For example, the high-level posterior distribution data calculator 184 calculates Z^{<POST>(l)}ₘ based on Expression (6).

$$\begin{matrix}[ Mathematical Expression 6 ] & \\ {Z}_{m + 1}^{〈 POST 〉 ( l )} = {arg max}_{Z} {h}_{j} ( Z ) & ( 6 )\end{matrix}$$

“argmax_{z}hⱼ(Z)” is a function for outputting “Z” that maximizes “hⱼ(Z)”.

hⱼ can be represented recursively as in Expression (7).

[Mathematical Expression 7]

hⱼ₊₁=hⱼ−μ\hat{ }^{(l)}_{Z|Y}ϵH (7)

The “H” in Expression (7) represents a reproducing kernel Hilbert space.

h₀ is represented as in Expression (8).

[Mathematical Expression 8]

h₀=μ\hat{ }^{(l)}_{Z|Y} (8)

After step S106, the process shifts to step S107.

### (Step S107)

The high-level posterior distribution data calculator 184 collects the M samples Z^{<POST>(l)}ₘ (m=1, . . . , M) in the sample Z^{<POST>(l)}. For example, the high-level posterior distribution data calculator 184 collects the M samples Z^{<POST>(l)}ₘ (m=1, . . . , M) in the sample Z^{<POST>(l)}, as indicated by Expression (9).

[Mathematical Expression 9]

[symbol]

^{(l)}=( [symbol] , . . . , [symbol] ) (9)

After step S107, the process shifts to step S108.

### (Step S108)

The data calculation device 100 executes a process for each low-level model 220. As mentioned above, the data calculation device 100 calculates the samples Z^{<PRED>(l)}ₛ by processing in the low-level models 220-s.

After step S108, the process shifts to step S109.

### (Step S109)

The high-level simulator 183 transfers the processing results for each low-level model 220 to the processing in the high-level model 210. Specifically, as mentioned above regarding the data calculation device 100, the high-level simulator 183 sets the values of the samples Z^{<PRI>(l+1)} based on the values of the samples Z^{<PRED>(l)}ₛ obtained for each of the low-level models 220. For example, the high-level simulator 183 sets the values of the samples Z^{<PRI>(l+1)} as indicated by Expression (10).

[Mathematical Expression 10]

[symbol]

=( [symbol] , . . . , [symbol] )^{T} (10)

After step S109, the process shifts to step S110.

### (Step S110)

The loop processor 182 counts up the values of the variable l used as a loop counter. That is, the loop processor 182 increments the value of the variable l by 1.

After step S110, the process shifts to step S102.

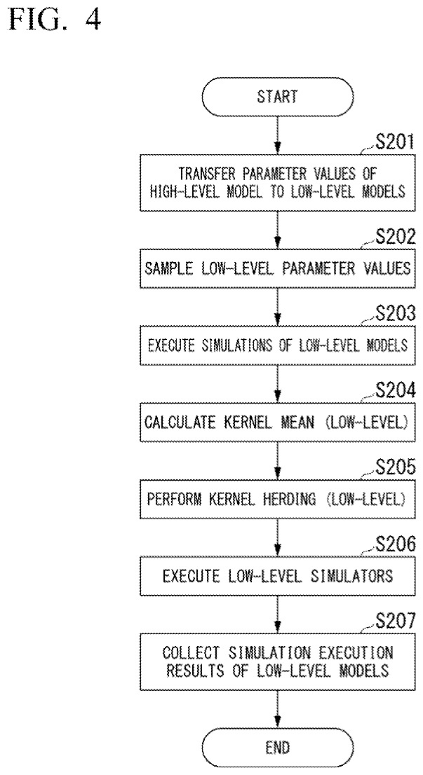

FIG. 4 is a flow chart depicting an example of a processing procedure performed for each low-level model 220 by the data calculation device 100. The data calculation device 100 performs the process of FIG. 4 in step S108 in FIG. 3.

### (Step S201)

The high-level posterior distribution data calculator 184 transfers the values of the parameter vector Z of the high-level model 210 to the low-level models 220. Specifically, as mentioned above regarding the data calculation device 100, the high-level posterior distribution data calculator 184 acquires samples Z′^{<POST>(l)}ₛ based on the samples Z^{<POST>(l)}. For example, the high-level posterior distribution data calculator 184 acquires Z′^{<POST>(l)}ₛ based on Expression (11).

[Mathematical Expression 11]

[symbol]

^{(l)}= [symbol] [s,:] (11)

Z^{<POST>(l)}[s,:] represents a row vector for the s-th row in the matrix Z^{<POSTT>(l)}.

In Expression (11), an apostrophe is added to the Z in order to distinguish it from Z^{<POST>(l)}ₘ.

Z′^{<POST>(l)}ₛ is expressed as in Expression (12).

[Mathematical Expression 12]

[symbol]

=( [symbol] , . . . , [symbol] ) (12)

Z′^{<POST>(l)}_{s,m} is expressed as in Expression (13).

[Mathematical Expression 13]

[symbol]

= [symbol] [s,m] (13)

Z^{<POST>(l)}[sm] represents the element in the s-th row and the m-th column in the matrix Z^{<POST>(l)}.

In the example of Expression (13), Z^{<POST>(l)} is configured as a matrix having the elements Z′^{<POST>(l)}_{s,m}. The high-level posterior distribution data calculator 184, as indicated by Expression (11), acquires M samples Z′^{<POST>(l)}_{s,l}, . . . , Z′^{<POST>(l)}_{s,M} to be used as target data for the low-level model 220-s by reading the s-th row in Z^{<POST>(l)}.

After step S201, the process shifts to step S202.

### (Step S202)

The low-level simulator 185 calculates M samples {θ^{<PRI>(l)}_{s,m}}ₘ₌₁^{M} from the prior distribution nos.

After step S202, the process shifts to step S203.

### (Step S203)

The low-level simulator 185 executes simulations by applying the samples θ^{<PRI>(l)}_{s,m} to the low-level models 220-s, thereby calculating the samples Z^{<PRI>(l)}_{s,m}.

The samples Z^{<PRI>(l)}_{s,m} are expressed as in Expression (14).

[Mathematical Expression 14]

[symbol]

=gₛ( [symbol] ) (14)

After step S203, the process shifts to step S204.

### (Step S204)

The low-level posterior distribution data calculator 186 calculates the kernel mean θ\hat{ }(l)_{θ|Z,s}. The kernel mean θ\hat{ }(l)_{θ|Z,s} is expressed as in Expression (15).

$$\begin{matrix}[ Mathematical Expression 15 ] & \\ {{μ}^{\hat{}}}_{θ \vert Z , s}^{( l )} = {{\sum }_{m = 1}}^{M} {{w}^{′}}_{s , m} {k}_{θ} ( \cdot , {θ}_{s , m}^{〈 PRI 〉 ( l )} ) & ( 15 )\end{matrix}$$

k_{θ} represents a kernel.

The weights w_{s,m} are expressed as in Expression (16).

[Mathematical Expression 16]

(w′_{s,1}, . . . , w′_{s,M})^{T}=(G_{z,s}+δMI)⁻¹K_{θ,s}(Z) (16)

G_{Z,s} represents a Gram matrix, which can be expressed as in Expression (17).

[Mathematical Expression 17]

G_{Z,S}={k_{θ}( [symbol] , [symbol] )}_{m,m′=1}^{M} (17)

K_{θ,s}(Z) represents the kernel of Z, and can be expressed as in Expression (18).

[Mathematical Expression 18]

K_{θ,s}(Z)=(k_{θ}( [symbol] ,Z), . . . , k_{θ}( [symbol] ,Z))^{T} (18)

After step S204, the process shifts to step S205.

### (Step S205)

The low-level posterior distribution data calculator 186 calculates samples {θ^{<POST>(l)}_{s,m}}ₘ₌₁^{M} of the parameters θₛ based on the kernel mean μ\hat{ }(l)_{θ|Z,s}.

For example, the low-level posterior distribution data calculator 186 calculates θ^{<POST>(l)}_{s,m} based on Expression (19).

$$\begin{matrix}[ Mathematical Expression 19 ] & \\ {θ}_{s , m + 1}^{〈 POST 〉 ( l )} = {arg max}_{θ} {h}_{s , j} ( θ ) & ( 19 )\end{matrix}$$

h_{s,j} is expressed recursively as in Expression (20).

[Mathematical Expression 20]

h_{s,j+1}=h_{s,j}+μ− [symbol] ϵH (20)

h_{s,0} is expressed as in Expression (21).

[Mathematical Expression 21]

h_{s,0}=μ\hat{ }_{θ|Z,s}^{(l)} (20)

After step S205, the process shifts to step S206.

### (Step S206)

The low-level simulator 185 executes simulations by setting the samples θ^{<POST>(l)}_{s,m} as the parameters of the low-level models 220-s, thereby calculating the samples Z^{<PRED>(l)}_{s,m}. Z^{<PRED>(l)}_{s,m} is expressed as in Expression (22).

[Mathematical Expression 22]

[symbol]

gₛ( [symbol] ) (22)

After step S206, the process shifts to step S207.

### (Step S207)

The low-level posterior distribution data calculator 186 collects M samples Z^{<PRED>(l)}_{s,m}(m=1, . . . , M) in the samples Z^{<PRED>(l)}ₛ.

After step S207, the data calculation device 100 ends the process in FIG. 4.

The process performed by the data calculation device 100 will be further explained by using an example.

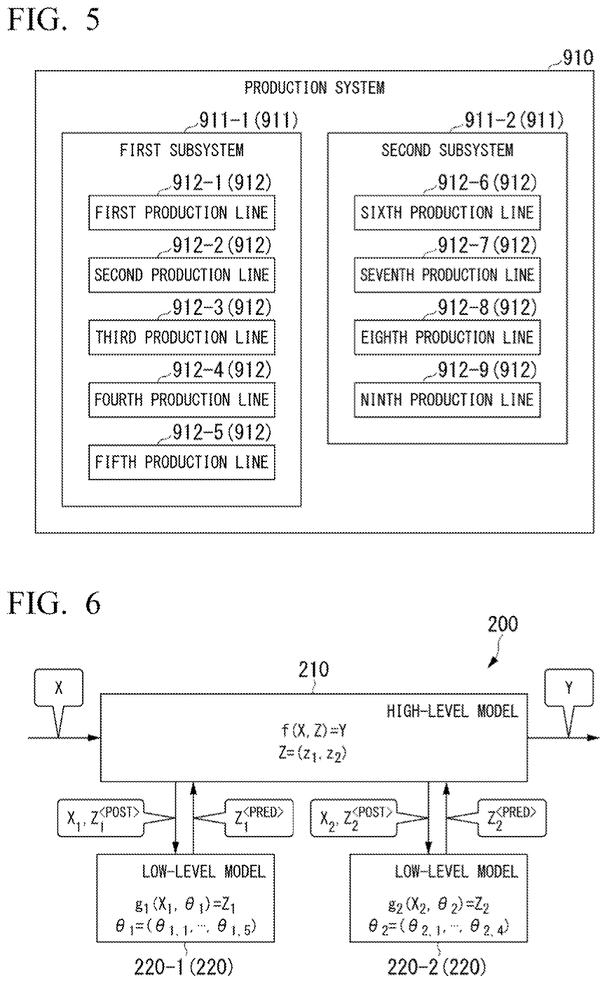

FIG. 5 is a diagram depicting the configuration of a production system 910 constituting an example of the subject 900. In the configuration depicted in FIG. 5, the production system 910 is provided with a first subsystem 911-1 and a second subsystem 911-2. The first subsystem 911-1 and the second subsystem 911-2 will be referred to collectively as subsystems 911.

The first subsystem 911-1 is provided with a first production line 912-1, a second production line 912-2, a third production line 912-3, a fourth production line 912-4, and a fifth production line 912-5. The second subsystem 911-2 is provided with a sixth production line 912-6, a seventh production line 912-7, an eighth production line 912-8, and a ninth production line 912-9. The first production line 912-1 to the ninth production line 912-9 will be referred to collectively as the production lines 912.

FIG. 6 is a diagram depicting an example of a model simulating the production system 910. In the example in FIG. 6, a low-level model 220 is provided for each subsystem 911. Thus, there are two low-level models 220.

The high-level model 210 is provided with two parameters z₁ and z₂ in accordance with the two low-level models. This is expressed by Z=(z₁, z₂).

The low-level model 220-1 is provided with five parameters θ_{1,1} to θ_{1,5} in accordance with the five production lines 912 from the first production line 912-1 to the fifth production line 912-5 provided in the first subsystem 911-1. This is expressed by θ₁=(θ_{1,1}, . . . , θ_{1,5}).

The low-level model 220-2 is provided with four parameters θ_{2,1} to θ_{2,4} in accordance with the four production lines 912 from the sixth production line 912-6 to the ninth production line 912-9 provided in the second subsystem 911-2. This is expressed by θ₂=(θ_{2,1}, . . . , θ_{2,4}).

As the outputs and parameters of the models, the time periods required to produce one production unit in each section, such as a product or a component, are used.

The parameters z₁, z₁ represent the time period required to produce one production unit, respectively, in the first subsystem 911-1 and in the second subsystem 911-2.

The parameters from θ_{1,1} to θ_{1,5} represent the time period required to produce one production unit from the first production line 912-1 to the fifth production line 912-5. The parameters from θ_{2,1} to θ_{2,4} represent the time periods required to produce one production unit from the sixth production line 912-6 to the ninth production line 912-9.

When target time periods are set as the target data, the target time periods and the outputs (the samples {Z^{<POST>(l)}ₘ}ₘ₌₁^{M}}) from the high-level model 210 to the low-level models 220 can be considered to indicate requirements relating to time, such as takt time. Meanwhile, the outputs (the samples {Z^{<PRED(l)}_{s,m}}ₘ₌₁^{M}}) from the low-level models 220 to the high-level model 210 can be considered to represent the times necessary for processing.

In this case, a solution that can satisfy both the required time periods and the necessary time periods can be considered to be found by the high-level model 210 and the low-level models 220 exchanging data.

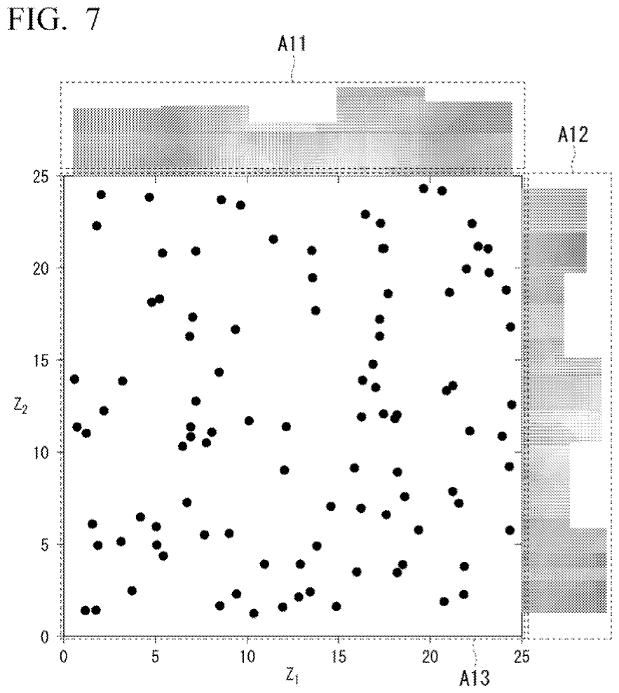

FIG. 7 is a diagram depicting an example of samples of parameter values in the high-level model 210 based on a prior distribution. The horizontal axis in FIG. 7 represents the values of the parameters z₁. The vertical axis represents the values of the parameters z₂.

The prior distribution of the parameters z₁ is indicated in region A11. The prior distribution of the parameters z₂ is indicated in region A12. Each of the points in region A13 indicate an example of a sample (z₁, z₂). The samples indicated in region A13 are expressed as {Z^{<PRI>(l)}ₘ}ₘ₌₁¹⁰⁰.

FIG. 7 depicts an example of samples of the parameters Z based on the prior distribution calculated by the initial setter 181 in step S102 in FIG. 3.

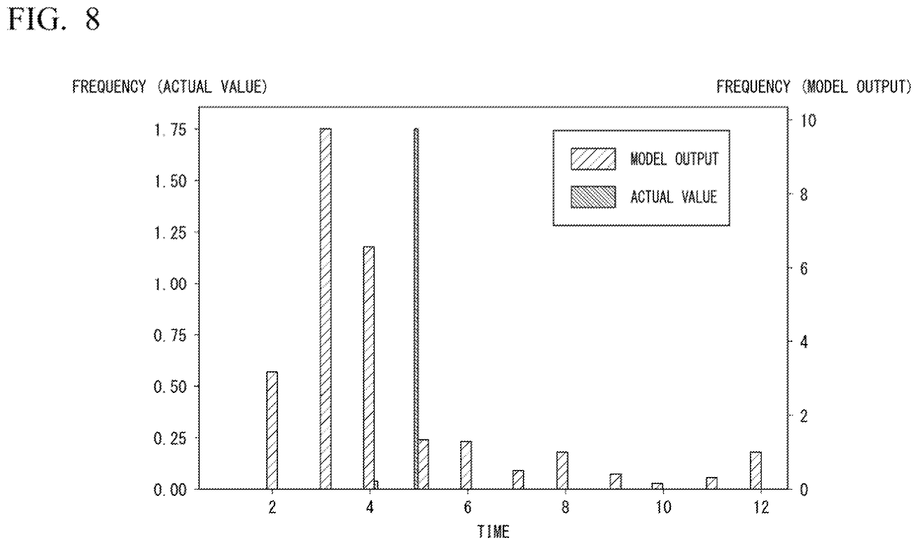

FIG. 8 is a diagram depicting a first example of samples of output values from the high-level model 210. The horizontal axis in FIG. 8 represents output values of the high-level model 210. The vertical axis represents the frequency of occurrence.

FIG. 8 represents, as a frequency distribution, the output values of the high-level model 210 obtained by executing simulations using the high-level model 210 for each value of the parameter vector Z shown in FIG. 7. These simulations are performed by the high-level simulator 183 in step S104 in FIG. 3.

The high-level posterior distribution data calculator 184 estimates the parameters Z such that, in the processes in steps S105 and S106 in FIG. 5, the model outputs depicted in FIG. 8 approach “5”, which is the actual value.

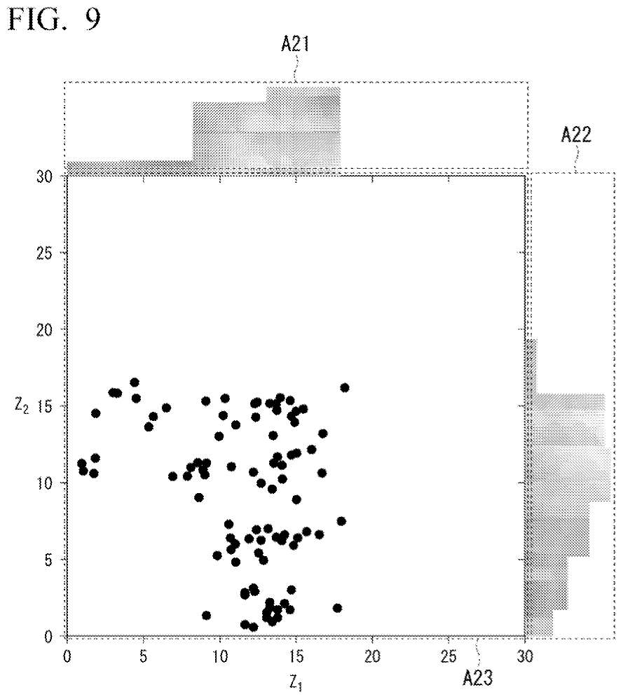

FIG. 9 is a diagram depicting an example of samples of parameter values in the high-level model 210 based on a posterior distribution. The horizontal axis in FIG. 9 represents the values of the parameters z₁. The vertical axis represents the values of the parameters z₂.

The posterior distribution of parameters z₁ is indicated in region A21. The posterior distribution of the parameters z₂ is indicated in region A22. Each of the points in region A23 indicate an example of a sample (z₁, z₂). The samples indicated in region A23 are expressed as {Z^{<POST>(l)}ₘ}ₘ₌₁¹⁰⁰.

FIG. 9 depicts an example of parameter values estimated by the high-level posterior distribution data calculator 184 using the model outputs and the actual values depicted in FIG. 8. In the case of the samples in the prior distribution of the parameters Z depicted in FIG. 7, the samples are plotted over the entire region A13. In contrast therewith, in the case of the samples in the posterior distribution of the parameters Z depicted in FIG. 9, most of the samples are plotted in the areas with z₁ values of about 10 to 15 and z₂ values of about 10 to 15.

The values of the parameters Z can be considered to have converged due to the data assimilation by the high-level posterior distribution data calculator 184.

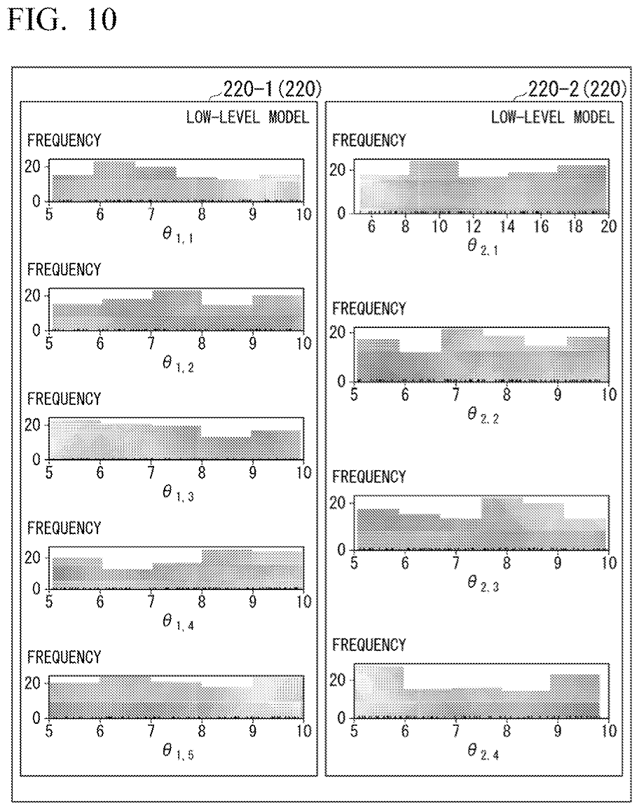

FIG. 10 is a diagram depicting an example of samples of parameter values in the low-level models 220 based on prior distributions.

FIG. 10 depicts, as frequency distributions with the parameter values on the horizontal axis and the frequencies on the vertical axis, samples based on the prior distribution for each of the parameters θ_{1,1} to θ_{1,5} in the low-level model 220-1 and the parameters θ_{2,1} to θ_{2,4} in the low-level model 220-2.

The low-level posterior distribution data calculator 186, in step S202 in FIG. 4, samples parameter values of the low-level models 220 based on the prior distributions indicated in FIG. 10.

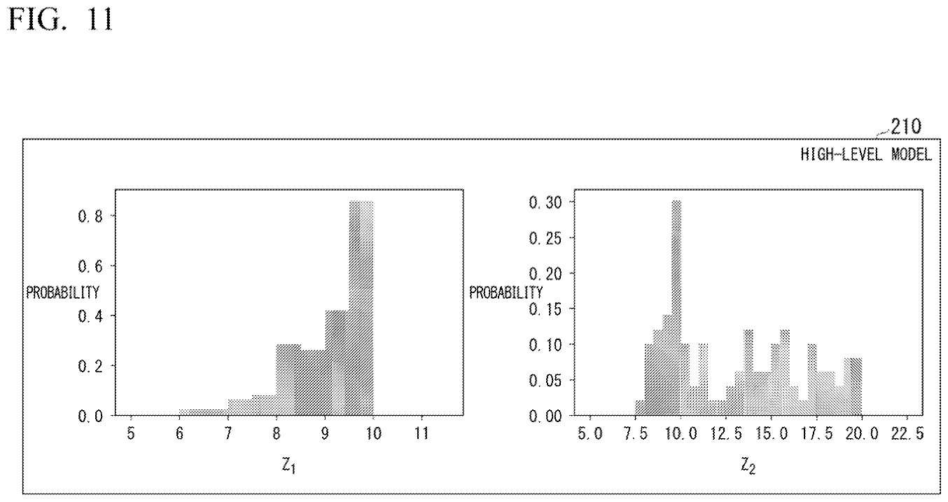

FIG. 11. is a diagram depicting an example of samples of output values from the low-level models 220. The horizontal axis in FIG. 11 represents output values from the low-level models 220. The vertical axis represents probabilities.

FIG. 11 depicts probability distributions of the output values from the low-level models 22 obtained by executing simulations by applying the parameter values indicated in FIG. 10 to the low-level models 220. These simulations are performed by the low-level simulator 185 in step S203 in FIG. 4.

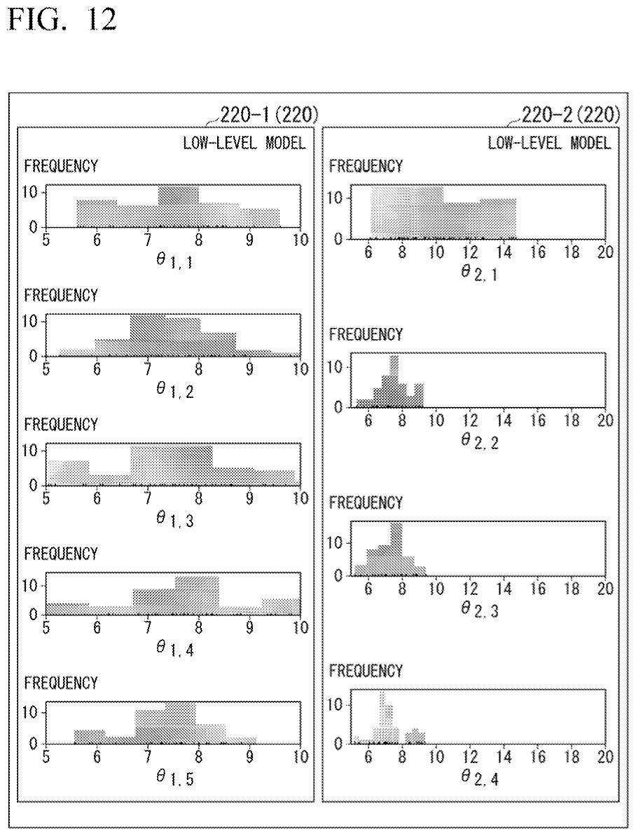

FIG. 12 is a diagram depicting an example of samples of parameter values in the low-level models 220 based on posterior distributions.

FIG. 12 depicts, as frequency distributions with the parameter values on the horizontal axis and the frequencies on the vertical axis, samples based on the posterior distribution for each of the parameters θ_{1,1} to θ_{1,5} in the low-level model 220-1 and the parameters θ_{2,1} to θ_{2,4} in the low-level model 220-2.

In steps S204 and S205 in FIG. 4, the low-level posterior distribution data calculator 186 performs data assimilation to calculate samples of the parameter values of the low-level models 220 based on posterior distributions.

Comparing FIG. 10 and FIG. 12, the parameter values are more unevenly distributed in FIG. 12 than in FIG. 10. The values of the parameters θ₁ and θ₂ can be considered to have converged due to the data assimilation by the low-level posterior distribution data calculator 186.

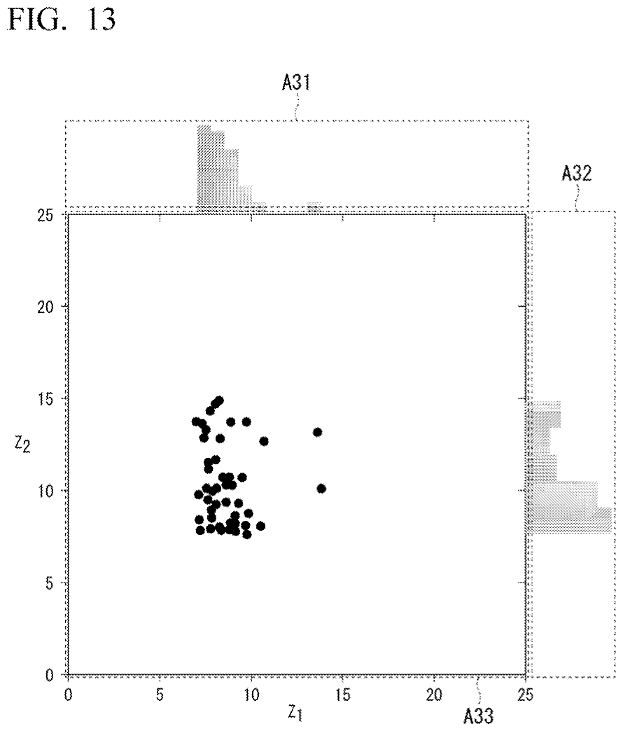

FIG. 13 is a diagram depicting an example of samples of output values from the low-level models 220. The horizontal axis in FIG. 13 represents the values of the parameters z₁. The vertical axis represents the values of the parameters z₂.

FIG. 13 depicts output values of the low-level models 220 in the case in which simulations are performed by applying the parameter values depicted in FIG. 12 to the low-level models 220. These simulations are performed by the low-level simulator 185 in step S206 in FIG. 4.

Each of the points in region A33 indicate an example of a sample (z₁, z₂). The samples indicated in region A33 are expressed as {Z^{<PRED>(l)}_{s,m}}ₘ₌₁¹⁰⁰.

Region A31 depicts the distribution of the parameters z₁ based on the samples depicted in region A33. Region A32 depicts the distribution of the parameters z₂ based on the samples depicted in region A33.

In FIG. 13, the parameter values are more unevenly distributed than in the case of FIG. 9, with most of the samples being plotted in the areas with z₁ values of about 6 to 10 and z₂ values of about 7 to 15.

The values of the parameters Z can be considered to have further converged by reflecting the results of data assimilation by the low-level posterior distribution data calculator 186.

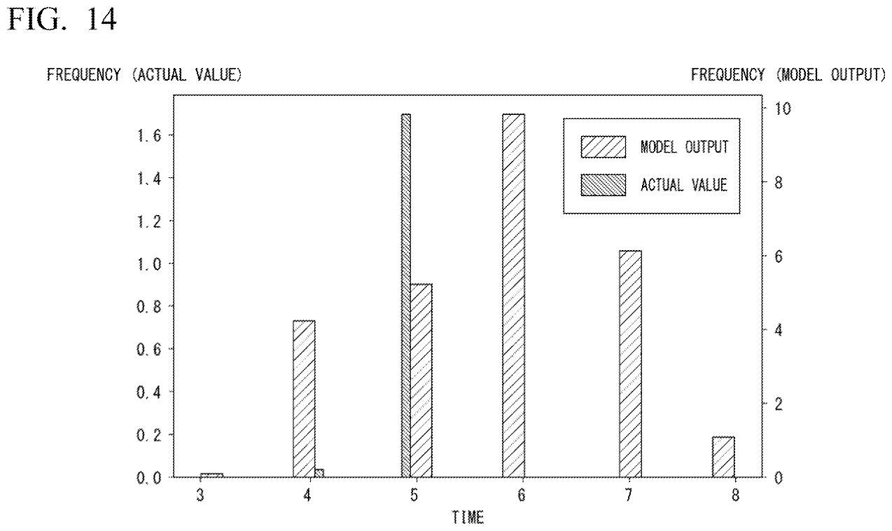

FIG. 14 is a diagram depicting a second example of samples of output values from the high-level model 210. The horizontal axis in FIG. 14 represents output values of the high-level model 210. The vertical axis represents the frequency of occurrence.

FIG. 14 represents, as a frequency distribution, an example of the outputs from the high-level model 210 in the case in which simulations have been executed by applying the parameter values depicted in FIG. 13 to the high-level model 210. The high-level simulator 183 performs these simulations in step S104 during the second execution of the loop from steps S103 to S110 in FIG. 3.

With the values of the parameters Z having further converged in the case of FIG. 13 than in the case of FIG. 7, the outputs of the high-level model 210 have further converged in the case of FIG. 14 than in the case of FIG. 8.

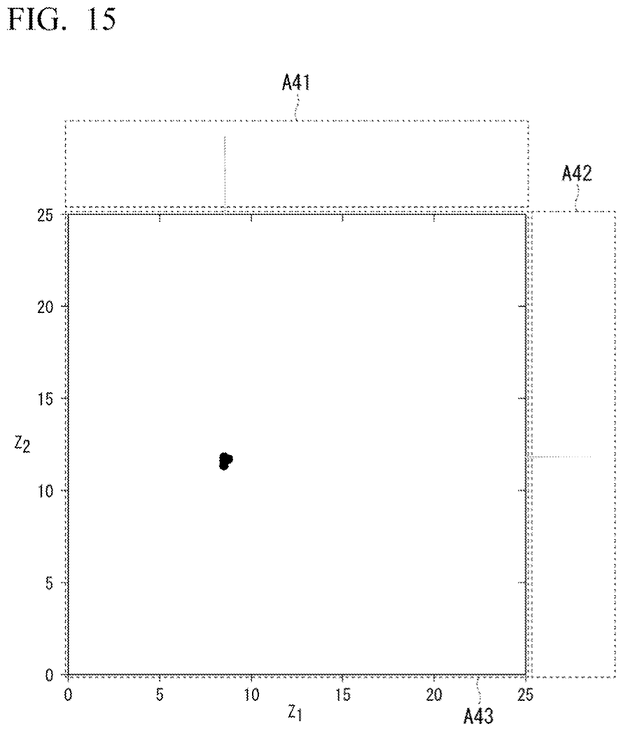

FIG. 15 is a diagram depicting a third example of parameter values for the high-level model 210. The horizontal axis in FIG. 15 represents values of the parameters z₁. The vertical axis represents values of the parameters z₂.

FIG. 15 depicts values of parameters for the high-level model 210 for the case in which data assimilation has been performed for estimating parameter values so that the output values from the high-level model 210 approach actual values based on the output values of the high-level model 210 depicted in FIG. 14. This data assimilation is performed by the high-level posterior distribution data calculator 184 in steps S104 and S105 during the second execution of the loop from steps S103 to S110 in FIG. 3.

Each of the points in region A34 indicate an example of a sample (z₁, z₂). The samples indicated in region A33 are expressed as {Z^{<PRED>(l)}_{s,m}}ₘ₌₁¹⁰⁰.

Region A41 depicts the distribution of the parameters z₁ based on the samples depicted in region A43. Region A42 depicts the distribution of the parameters z₂ based on the samples depicted in region A33.

In FIG. 15, the parameter values are more unevenly distributed than in the case of FIG. 13, with the z₁ values being concentrated at about 9 and the z₂ values being concentrated at about 12.

The data calculation device 100 can be considered to have succeeded in estimating appropriate values for the parameters Z.

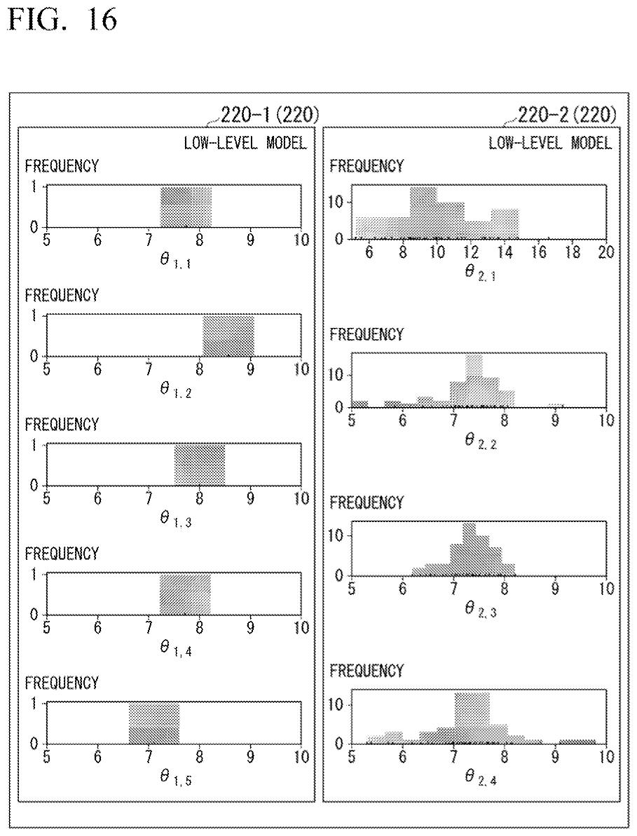

FIG. 16 is a diagram depicting an example of estimation results for parameter values in the low-level model 220 by the data calculation device 100.

FIG. 16 depicts, as frequency distributions with the parameter values on the horizontal axis and the frequencies on the vertical axis, an example of the parameter values of the low-level models 220 in the case in which, with the parameter values of the high-level model 210 depicted in FIG. 15 as the target values for the outputs from the low-level models 220, data assimilation has been performed for estimating the parameter values of the low-level models 220 so that the output values of the low-level models 220 approach the target values.

This data assimilation is performed by the low-level posterior distribution data calculator 186 in steps S204 and S205 during the second execution of the process in FIG. 4.

In FIG. 16, the parameter values are more unevenly distributed than in the case of FIG. 12. The data calculation device 100 can be considered have succeeded in estimating appropriate values for the parameters θ₁ and θ₂.

The model 200 may be configured as a model with three or more layers. In this case, the highest-layer model is referred to as the high-level model and the lowest-layer model is referred to as the low-level model, and models in other layers are referred to as intermediate models.

Even in the case in which there are three or more layers in a model, the process relating to the high-level model is the same as that explained with reference to FIG. 3. In the case in which the model for directly inputting/outputting data with respect to the high-level model is an intermediate model, the “low-level model” in the explanation in FIG. 3 can simply be reworded to be an intermediate model.

Even in the case in which there are three or more layers in a model, the process relating to the low-level model is the same as that explained with reference to FIG. 4. In the case in which the model for directly inputting/outputting data with respect to the low-level model is an intermediate model, the “high-level model” in the explanation in FIG. 4 can simply be reworded to be an intermediate model.

Regarding the intermediate layers, in addition to the process in FIG. 4, the process from steps S107 to S109 in FIG. 3 are performed between steps S205 and S206.

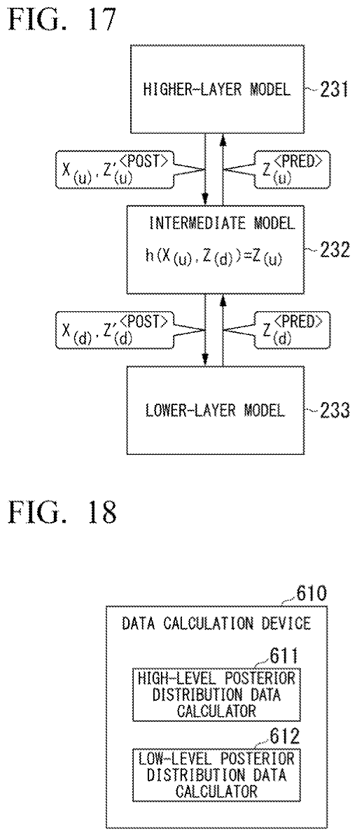

In this case, the input/output data for the intermediate layer is denoted as in FIG. 17.

FIG. 17 is a diagram depicting an example of the input/output of data in an intermediate layer in the case in which there are three or more layers in a model. In the example in FIG. 17, the intermediate model 232 inputs/outputs data with respect to the higher-layer model 231 and the lower-layer model 233. The higher-layer model 231 is a model in a layer immediately above the intermediate model 232. The higher-layer model 231 may be the high-level model or may be an intermediate model.

The lower-layer model 233 is a model in a layer immediately below the intermediate model 232. The lower-layer model 233 may be the low-level model or may be an intermediate model.

The number of intermediate models that input/output data with respect to a single higher-layer model 231 may be one or more. The number of lower-layer models that input/output data with respect to a single intermediate model 232 may be one or more.

The number of layers of models need not be uniform. For example, the models in a layer immediately below the high-level model may be both an intermediate model and a low-level model. The models in a layer immediately below an intermediate model may be both an intermediate model and a low-level model.

Regarding the input vectors, the data calculation device 100 sets input vectors X₍ᵤ₎ that are to be input to the intermediate model 232 and input vectors X_{(d)} that are to be input to the lower-layer model 233. This corresponds to the data calculation device 100 hierarchically performing the process for setting the input vectors Xₛ to the low-level models 220-s as mentioned above.

Regarding the samples of the model parameters, samples output from the higher-layer model 231 to the intermediate model 232 are denoted by Z′^{<POST>}₍ᵤ₎. Samples output from the intermediate model 232 to the lower-layer model 233 are denoted by Z′<POST>_{(d)}.

Z′^{<POST>}₍ᵤ₎ and Z′^{<POST>}_{(d)} correspond to Z′^{<POST>(l)}_{s,l}, . . . , Z′^{<POST>(l)}_{s,M} in the process in FIG. 4. Z′^{<POST>}₍ᵤ₎ is used as target data for data assimilation in the intermediate model 232. Z′^{<POST>}₍ᵤ₎ is used as target data for data assimilation in the lower-layer model 233.

Samples output from the lower-layer model 233 to the intermediate model 232 are denoted by Z^{<PRED>}_{(d)}. Samples output from the intermediate model 232 to the higher-layer model 231 are denoted by Z^{<PRED>}₍ᵤ₎.

Z^{<PRED>}_{(d)} and Z^{<PRED>}₍ᵤ₎ correspond to Z^{<PRED>(l)}ₛ in the process in FIG. 3 and the process in FIG. 4. Z^{<PRED>}_{(d)} is used for updating the samples Z^{<POST>}_{(d)} based on the posterior distribution in the intermediate model 232. The samples based on the posterior distribution mentioned here are samples obtained by data assimilation, and correspond to samples of the parameters based on the posterior distribution when the target data for the output values of the model have been provided.

When the higher-layer model 231 is an intermediate model, Z^{<PRED>}₍ᵤ₎ is used for updating the samples Z^{<POST>}_{(d)} that are based on the posterior distribution in the higher-layer model 231. Meanwhile, in the case in which the higher-layer model 231 is the high-level model, Z^{<PRED>}₍ᵤ₎ is used for generating samples based on the prior distribution when executing the next loop in the higher-layer model 231.

The data calculation device 100 performs data assimilation for estimating the values of the parameters Z_{(d)} so that the values of the outputs Zᵤ from the intermediate model 232 approach the values of the target data Z^{<POST>}₍ᵤ₎ by means of a process corresponding to steps S201 to S205 in FIG. 4. In this way, the data calculation device 100 calculates the samples Z^{<POST>}_{(d)}.

Furthermore, the data calculation device 100 calculates the samples Z^{<PRED>}_{(d)} reflecting the results of data assimilation by the lower-layer model 233 by means of a process corresponding to steps S107 to S109 in FIG. 3.

In step S109 in FIG. 3, the data calculation device 100 calculates Z^{<PRI>(l+1)} by using Z^{(PRED)(l)}ₛ. In contrast therewith, in a process on the intermediate model 232, the data calculation device 100 uses Z^{<PRED>}_{(d)} to update the samples Z^{<POST>}_{(d)} based on the posterior distribution.

Furthermore, the data calculation device 100 calculates Z^{<PRED>}₍ᵤ₎ by executing simulations by applying the updated samples Z^{<POST>}_{(d)} to the intermediate model 232 by means of a process corresponding to steps S206 and S207 in FIG. 4.

Thus, the process relating to the intermediate model 232 differs from the process in FIG. 4 in that, after data assimilation in the intermediate model 232, Z^{<PRED>}₍ᵤ₎ is calculated by reflecting the results of data assimilation in the lower-layer model 233 in the samples Z^{<POST>}_{(d)}. In all other respects, the process relating to the intermediate model is the same as the process in FIG. 4.

As indicated above, the high-level posterior distribution data calculator 184 calculates data {Z^{POST>(l)}ₘ}ₘ₌₁^{M} indicating a posterior distribution of parameter values of the high-level model 210 based on target data for the outputs from the high-level model 210. The low-level posterior distribution data calculator 186 calculates, for the low-level models 220, data {θ<POST>(l)ₘ}ₘ₌₁^{M} indicating posterior distributions of parameter values of the lower-level models 220 based on data {Z^{POST>(l)}ₘ}ₘ₌₁^{M} indicating a posterior distribution of parameter values of the high-level model 210.

Data assimilation can be hierarchically performed by the low-level posterior distribution data calculator 186 calculating data indicating posterior distributions of the parameter values in the low-level models 220 by using the parameter values of the high-level model 210. Specifically, by having the low-level posterior distribution data calculator 186 use the target values (samples Z^{<POST>}ₛ) for the outputs from the low-level model 220 decided based on the samples Z^{<POST>} after adjustment of the parameter values in the high-level model 210, the adjustment results for the parameter values in the high-level model 210 can be reflected in adjustment of the parameter values in the low-level models 220.

Due to the number of dimensions in the parameter vector Z being smaller than the total number of dimensions of the parameter vectors θ₁ to θ_{S}, the number of parameters in each model can be reduced in comparison with the case in which the subject 900 is simulated by only a single model. For this reason, the data calculation device 100 is expected to be able to perform data assimilation and to estimate the values of the parameter vectors θ₁ to θ_{S} in a relatively short time. In particular, the data calculation device 100 is expected to be able to avoid situations in which estimated values of parameters cannot be obtained within a practical time period due to the number of parameters in a model being too large.

Additionally, data is not directly exchanged between the low-level models 220, and each of the low-level models 220 perform processing in parallel. The data calculation device 100 is expected to be able to perform data assimilation in a relatively short time period for this reason as well.

Additionally, the low-level simulator 185 executes simulations by applying, to the low-level models 220, parameter values θ^{<POST>} based on data {θ^{<POST>(l)}ₘ}ₘ₌₁^{M} indicating posterior distributions of the parameter values of the low-level models 220. The high-level simulator 183 executes simulations by applying, to the high-level model 210, sample data {Z^{<PRI>(l+1)}ₘ}ₘ₌₁^{M} of parameter values of the high-level model 210 based on the results {Z^{<PRED>(l)}_{s,m}}ₘ₌₁^{M} of simulations using the low-level models 220. The high-level posterior distribution data calculator 184 calculates data {Z^{<POST>(l+1)}ₘ}ₘ₌₁^{M} indicating posterior distributions of the parameter values of the high-level model 210 based on target values for the outputs of the high-level model 210 based on the similarity between target data and sample data {Y^{<PRI>(l+1)}ₘ}ₘ₌₁^{M} of the outputs from the high-level model 210 obtained as a result of simulations using the high-level model 210.

In this way, the data calculation device 100 can have the results of data assimilation in the low-level models 220 be reflected in the parameter values for the high-level model 210. As a result, hierarchical data assimilation can be repeated. The data calculation device 100 is expected to be able to estimate parameter values with high accuracy by repeatedly performing hierarchical data assimilation. In particular, the probability distribution of the parameter vector Z and the respective probability distributions of the parameter vectors θ₁ to θ_{S} are all expected to converge to certain parameter values in accordance with target values. As mentioned above, the probability distributions converging to certain parameter values means that the probabilities become greater at those values.

For example, data assimilation relatively increases the probability that the values of the parameters Z will cause the values of the output vector Y to approach the target values, thereby causing many of the sampled values of the output vector Y to approach the target values when further data assimilation is performed. As a result, the probability that the values of the parameters Z will be values causing the value of the output vector Y to approach the target values due to further data assimilation can be expected to become even greater.

Regarding the parameter vectors θ₁ to θ_{S} also, the probabilities of the parameter values being in agreement with the target values can be expected to become greater as data assimilation is repeated.

Additionally, the outputs (Y^{<PRI>(l+1)}ₘ}ₘ₌₁^{M} from the high-level model 210 can be considered to be concentrated near specific values in accordance with the results of the data assimilations in the low-level models 220 by the execution of the simulations by the high-level simulator 183. By the high-level posterior distribution data calculator 184 using these outputs (Y^{<PRI>(l+1)}ₘ}ₘ₌₁^{M} to perform data assimilation, parameter values serving as solutions for data assimilation can be searched in a concentrated manner near specific values of the outputs of the high-level model 210. For this reason, the data calculation device 100 is expected to be able to estimate the parameter values more efficiently than in the case in which a single-layer model is used to perform a uniform search in parameter space.

Additionally, the high-level posterior distribution data calculator 184 calculates data {Z^{<POST>(l)}ₘ}ₘ₌₁^{M} indicating posterior distributions of parameter values of the high-level model 210 by executing kernel herding based on a kernel mean of sample data of parameter values of the high-level model 210.

In this way, the high-level posterior distribution data calculator 184 calculates data indicating posterior distributions of parameter values of the high-level model 210 based on a kernel mean. Thus, for M prior distribution samples that are given, the same number, M, of posterior distribution samples can be calculated. For this reason, the data calculation device 100 can efficiently estimate the parameter values.

Additionally, the low-level posterior distribution data calculator 186 calculates data {θ<POST>(l)ₘ}ₘ₌₁^{M} indicating posterior distributions of the parameter values of the low-level models by executing kernel herding based on a kernel mean of sample data of parameter values of the low-level models 220.

In this way, the low-level posterior distribution data calculator 186 calculates data indicating posterior distributions of parameter values of the low-level models 220 based on a kernel mean. Thus, for M prior distribution samples that are given, the same number, M, of posterior distribution samples can be calculated. For this reason, the data calculation device 100 can efficiently estimate the parameter values.

Additionally, the controller 180 controls the subject 900 based on the data indicating the posterior distributions of the parameter values of the low-level models 220 calculated by the low-level posterior distribution data calculator 186.

As described above, since the data calculation device 100 uses hierarchical models, there are relatively few parameters in each of the models. Thus, even in cases in which the subject 900 is relatively complex, the low-level posterior distribution data calculator 186 can estimate the parameter values of the low-level model 220. By referring to the parameter value estimation results from the low-level posterior distribution data calculator, the controller 180 can recognize the state of the subject 900 and control the subject 900 with relatively high accuracy.

FIG. 18 is a diagram depicting an example of the configuration of a data calculation device according to an example embodiment. In the configuration depicted in FIG. 18, the data calculation device 610 is provided with a high-level posterior distribution data calculator 611 and a low-level posterior distribution data calculator 612. In this configuration, the high-level posterior distribution data calculator 611 calculates data indicating a posterior distribution of parameter values of the high-level model based on target data for the outputs of the high-level model that simulates a subject. The low-level posterior distribution data calculator 612 calculates, for low-level models that simulate portions of the subject and that output parameter values of the high-level model, data indicating posterior distributions of parameter values for the low-level models, based on the data indicating the posterior distribution of parameter values for the high-level model.

The high-level posterior distribution data calculator 611 corresponds to an example of high-level posterior distribution data calculating means. The low-level posterior distribution data calculator 612 corresponds to an example of low-level posterior distribution data calculating means.

The low-level posterior distribution data calculator 612 can perform hierarchical data assimilation by calculating data indicating the posterior distributions of parameter values of the low-level models by using the parameter values of the high-level model. Specifically, by using target values for the outputs of the low-level models that are decided based on samples of the parameter values after data assimilation in the high-level model, the low-level posterior distribution data calculator 612 can have the results of data assimilation in the high-level model be reflected in the data assimilation in the low-level models.

By making the number of parameters in the high-level model less than the total number of parameters in the low-level models, the number of parameters in each model can be made less than that in the case of simulating the subject with only one model. For this reason, the data calculation device 610 is expected to be able to perform data assimilation and to be able to estimate parameter values in a relatively short time period. In particular, the data calculation device 610 is expected to be able to avoid situations in which estimated values of parameters cannot be obtained within a practical time period due to the number of parameters in a model being too large.

Additionally, data is not directly exchanged between the low-level models, and each of the low-level models can perform processing in parallel. The data calculation device 610 is expected to be able to perform data assimilation in a relatively short time period for this reason as well.

The high-level posterior distribution data calculator 611 can be realized, for example, by using the functions of the high-level posterior distribution data calculator 184, etc. indicated in FIG. 1. The low-level posterior distribution data calculator 612 can be realized, for example, by using the functions of the low-level posterior distribution data calculator 186 depicted in FIG. 1.

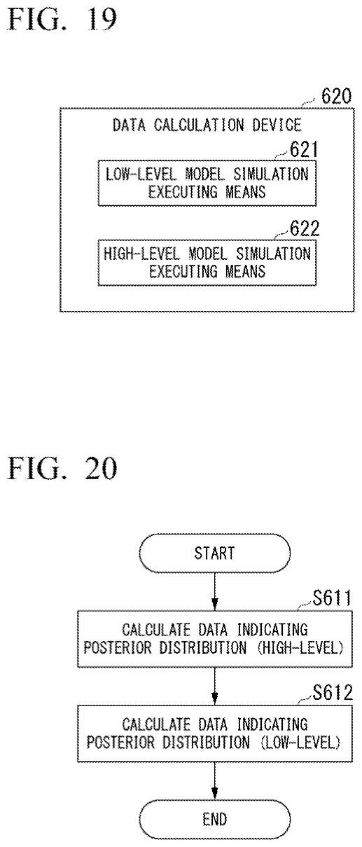

FIG. 19 is a diagram depicting one more example of the configuration of the data calculation device according to an example embodiment. In the configuration depicted in FIG. 19, the data calculation device 620 is provided with a low-level model simulation execution unit 621 and a high-level model simulation execution unit 622.

In this configuration, the low-level model simulation execution unit 621 calculates data indicating a distribution of parameter values for a high-level model by executing simulations by applying data indicating distributions of the parameter values of low-level models to the low-level models, which output parameter values of the high-level model that simulates a subject. The high-level model simulation execution unit 622 executes simulations of the subject by applying the calculated data indicating distributions of parameter values.

The low-level model simulation execution unit 621 corresponds to an example of low-level model simulation executing means. The high-level model simulation execution unit 622 corresponds to an example of high-level model simulation executing means.

According to the data calculation device 620, estimated results of the parameter values using the low-level model can be reflected in the high-level model. For this reason, simulations of the subject can be performed with high accuracy.

The low-level model simulation execution unit 621 can, for example, be realized by using the functions of the low-level simulator 185, etc. depicted in FIG. 1. The high-level model simulation execution unit 622 can, for example, be realized by using the functions of the high-level simulator 183, etc. depicted in FIG. 1.

FIG. 20 is a diagram depicting an example of the processing procedure in a data calculation method according to an example embodiment. The data calculation method depicted in FIG. 20 includes a step of calculating data indicating a posterior distribution for a high-level model (step S611), and a step of calculating data indicating posterior distributions for low-level models (step S612).

In the step of calculating data indicating a posterior distribution for a high-level model (step S611), data indicating a posterior distribution of parameter values for the high-level model that simulates a subject are calculated based on target data for outputs of the high-level model.

In the step of calculating data indicating posterior distributions for low-level models (step S612), for the low-level models that simulate portions of the subject and that output parameter values of the high-level model, data indicating posterior distributions of parameter values for the low-level models are calculated based on the data indicating the posterior distribution of parameter values for the high-level model.

According to the data calculation method depicted in FIG. 20, data assimilation can be hierarchically performed by using parameter values for the high-level model to calculate data indicating posterior distributions of parameter values in the low-level models. Specifically, the results of data assimilation in the high-level model can be reflected in data assimilation in the low-level models by using target values for the outputs from the high-level model decided based on samples of the parameter values after data assimilation in the high-level model.

By making the number of parameters in the high-level model less than the total number of parameters in the low-level models, the number of parameters in each model can be made less than that in the case of simulating the subject with only one model. For this reason, the data calculation method depicted in FIG. 20 is expected to be able to perform data assimilation and to be able to estimate parameter values in a relatively short time period. In particular, the data calculation method depicted in FIG. 20 is expected to be able to avoid situations in which estimated values of parameters cannot be obtained within a practical time period due to the number of parameters in a model being too large.

Additionally, data is not directly exchanged between the low-level models, and each of the low-level models perform processing in parallel. The data calculation method depicted in FIG. 20 is expected to be able to perform data assimilation in a relatively short time period for this reason as well.

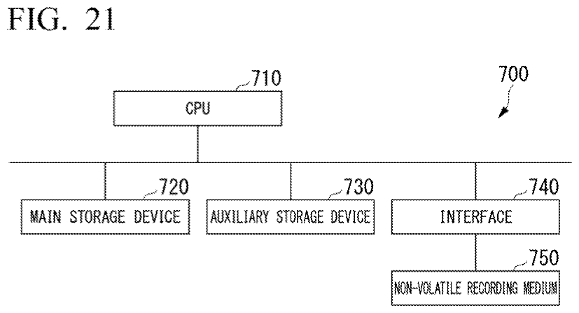

FIG. 21 is a schematic block diagram depicting the configuration of a computer according to at least one example embodiment.

In the configuration depicted in FIG. 21, a computer 700 is provided with a CPU 710, a main storage device 720, an auxiliary storage device 730, an interface 740, and a non-volatile recording medium 750.

One or more of the data calculation device 100 and the data calculation device 610 mentioned above, or portions thereof, may be installed in the computer 700. In that case, the above-mentioned operations of the respective processors are stored in the auxiliary storage device 730 in the form of a program. The CPU 710 reads the program from the auxiliary storage device 730, loads it in the main storage device 720, and executes the above-mentioned processes in accordance with said program. Additionally, the CPU 710 secures storage areas corresponding to the respective storages mentioned above in the main storage device 720 in accordance with the program. Communication between the respective devices and other devices is executed by the interface 740 having a communication function and communicating in accordance with control by the CPU 710. Additionally, the interface 740 has a port for use by the non-volatile recording medium 750, and reads out information from the non-volatile recording medium 750 and writes information into the non-volatile storage medium 750.

In the case in which the data calculation device 100 is loaded in the computer 700, the operations of the controller 180 and the respective units thereof are stored in the auxiliary storage device 730 in the form of a program. The CPU 710 reads the program from the auxiliary storage device 730, loads it in the main storage device 720, and executes the above-mentioned processes in accordance with said program.

Additionally, the CPU 710 secures, in the main storage device 720, a storage area corresponding to the storage 170 in accordance with the program.

Communication with other devices by the communicator 110 is executed by the interface 740 having a communication function and operating in accordance with control by the CPU 710.

Display by the display 120 is executed by the interface 740 having a display device that displays various images in accordance with control by the CPU 710.

Reception of user operations by the operation input 130 is executed by the interface 740 having an input device such as, for example, a keyboard and a mouse, receiving user operations, and outputting information indicating the received user operations to the CPU 710.

In the case in which the data calculation device 610 is loaded in the computer 700, the operations of the high-level posterior distribution data calculator 611 and the low-level posterior distribution data calculator 612 are stored in the auxiliary storage device 730 in the form of a program. The CPU 710 reads the program from the auxiliary storage device 730, loads it in the main storage device 720, and executes the above-mentioned processes in accordance with said program.

Additionally, the CPU 710 secures, in the main storage device 720, a storage area for the processes performed by the data calculation device 610 in accordance with the program.

Communication between the data calculation device 610 and other devices is executed by the interface 740 having a communication function and operating in accordance with control by the CPU 710.

Interactions between the data calculation device 610 and a user are executed by the interface 740 having an input device and an output device, presenting the user with information by means of the output device in accordance with control by the CPU 710, and receiving user operations by means of the input device.

One or more of the programs mentioned above may be recorded on the non-volatile recording medium 750. In this case, the interface 740 may read the program from the non-volatile recording medium 750. Furthermore, the CPU 710 may directly execute the program read by the interface 740, or may execute the program by temporarily storing it in the main storage device 720 or the auxiliary storage device 730.

A program for executing all or some of the processes performed by the data calculation device 100 and the data calculation device 610 may be recorded in a computer-readable recording medium, and the program recorded in this recording medium may be read into a computer system and executed to perform the processes in the respective units. The “computer system” mentioned here includes an OS and hardware such as peripheral devices.

Additionally, the “computer-readable recording medium” refers to portable media such as flexible disks, magneto-optic disks, ROMs (Read-Only Memory), or CD-ROMs (Compact Disc Read-Only Memory), and to storage devices such as hard disks that are internal to a computer system. Additionally, the program may be for realizing some of the aforementioned functions, or further thereto, may realize the aforementioned functions by being combined with a program that is already recorded in the computer system.

Example Embodiments of the present invention have been explained in detail with reference to the drawings above. However, the specific configuration is not limited to these example embodiments described above, and designs or the like within a scope not departing from the gist of the present invention are also included.

### INDUSTRIAL APPLICABILITY

The example embodiments of the present invention can be applied to data calculation devices, data calculation methods, and recording media.

### REFERENCE SIGNS LIST

100, 610 Data calculation device
110 Communicator
120 Display
130 Operation input
170 Storage
180 Controller
181 Initial setter
182 Loop processor
183 High-level simulator
184, 611 High-level posterior distribution data calculator
185 Low-level simulator
186, 612 Low-level posterior distribution data calculator

What is claimed is:

1. A data calculation device comprising:
a memory configured to store instructions; and
a processor configured to execute the instructions to:
calculate data indicating a posterior distribution of parameter values of a high-level model that simulates a subject, based on target data for outputs from the high-level model; and
calculate for a low-level model that simulates a portion of the subject and that outputs parameter values of the high-level model, data indicating a posterior distribution of parameter values of the low-level model, based on the data indicating a posterior distribution of parameter values of the high-level model.

2. The data calculation device according to claim 1,
wherein the processor is configured to further execute the instructions to:
execute a simulation by applying, to the low-level model, parameter values based on the data indicating a posterior distribution of parameter values of the low-level model;
execute a simulation by applying, to the high-level model, sample data of parameter values of the high-level model based on results of a simulation using the low-level model; and
calculate, based on similarities between the target data and sample data of outputs from the high-level model obtained as a result of the simulation, data indicating a posterior distribution of parameter values of the high-level model based on target data for outputs from the high-level model.

3. The data calculation device according to claim 1,
wherein the processor is configured to further execute the instructions to:
calculate the data indicating a posterior distribution of parameter values of the high-level model by executing kernel herding based on a kernel mean of sample data of parameter values of the high-level model.

4. The data calculation device according to claim 1,
wherein the processor is configured to further execute the instructions to:
calculate the data indicating a posterior distribution of parameter values of the low-level model by executing kernel herding based on a kernel mean of sample data of parameter values of the low-level model.

5. The data calculation device according to claim 1,
wherein the processor is configured to further execute the instructions to:
control the subject based on the data indicating a posterior distribution of parameter values of the calculated low-level model.

6. A data calculation device comprising:
a memory configured to store instructions; and
a processor configured to execute the instructions to:
execute a simulation by applying, to a low-level model that outputs parameter values of a high-level model that simulates a subject, data indicating a distribution of parameter values of the low-level model, thereby calculating data indicating a distribution of the parameter values of the high-level model; and
execute a simulation of the subject by applying, to the high-level model, the data indicating a distribution of parameter values that have been calculated.

7. A data calculation method by a computer, the data calculation method comprising:
calculating data indicating a posterior distribution of parameter values of a high-level model that simulates a subject, based on target data for outputs from the high-level model; and
calculating, for a low-level model that simulates a portion of the subject and that outputs parameter values of the high-level model, data indicating a posterior distribution of parameter values of the low-level model, based on the data indicating a posterior distribution of parameter values of the high-level model.

8. (canceled)
